(19) United States
(12) Patent Application Publication
(10) Pub. No.: US 2013/0160830 A1
(43) Pub. Date: Jun. 27, 2013

(54) THICK-FILM CONDUCTIVE PASTE COMPOSITION

(71) Applicant: Alex Sergey IONKIN, Kennett Square, PA (US)

(72) Inventor: Alex Sergey IONKIN, Kennett Square, PA (US)

(73) Assignee: E.I. DU PONT DE NEMOURS AND COMPANY, Wilmington, DE (US)

(21) Appl. No.: 13/332,593

(22) Filed: Dec. 21, 2011

(51) Int. Cl. H01B 1/22; H01L 21/283; H01L 31/0224; H01B 1/02; H01L 23/482

(52) U.S. Cl. 136/256; 252/512; 257/741; 438/660; 257/E23.018; 257/E21.159

(57) ABSTRACT

A conductive thick-film paste composition is useful in forming conductive structures on the front side of a solar cell or other like device. The paste composition has a source of electrically conductive metal, such as silver powder, one or more glass components, and an optional zinc-containing additive, which are dispersed in an organic medium containing a surfactant.

### FIELD OF THE INVENTION

The present invention pertains generally to a conductive paste composition and a device made therewith, and more particularly, to a paste composition comprising a source of an electrically conductive metal, one or more glass frits, and an optional zinc-containing additive that are all dispersed in an organic medium that includes an ammonium-containing surfactant.

### BACKGROUND

A conventional solar cell structure with a p-type base has a negative electrode that is typically on the front side or sun side of the cell and a positive electrode on the backside. It is well-known that radiation of an appropriate wavelength falling on a p-n junction of a semiconductor body serves as a source of external energy to generate electron-hole pairs in that body. Because of the potential difference which exists at a p-n junction, electrons and holes move across the junction in opposite directions, thereby giving rise to flow of an electric current that is capable of delivering power to an external circuit connected to a cell having such a junction. Solar cells commonly are constructed using a silicon wafer substrate that has been metallized, i.e., provided with metal contacts that are electrically conductive.

Although various methods and compositions for forming solar cells exist, there remains a need for compositions, structures, and devices which have improved electrical performance, and methods of making such devices.

### SUMMARY OF THE INVENTION

An aspect of the present invention provides a paste composition comprising in admixture:
a) about 75 to about 99% by weight based on solids of a source of an electrically conductive metal;
b) about 0.1 to about 10% by weight based on solids of at least one glass component;
c) 0 to about 15% by weight based on solids of an optional zinc-containing additive that is at least one of zinc oxide, a compound that generates zinc oxide upon firing, zinc metal, a zinc alloy, or a mixture thereof; and
d) an organic medium in which the components a) through c) are dispersed, the organic medium comprising about 0.01 to about 10% by weight based on total composition of a surfactant having a formula:

(R1)(R2)(R3)(R4)N⁺X⁻,
wherein each of R1, R2, R3, and R4 is separately an alkyl, alkyl/aryl, alkyl/heteroaryl, or polyethylene glycol group, and X⁻ is a halide, alkylsulfonate, alkylsulfate, alkylphosphate, alkylcarboxylate, arylcarboxylate, dodecylbenzenesulfonate, dicyanamide, bis(2,4,4-trimethylpentyl)phosphinate, dibutyl phosphate, hexafluorophosphate, or a combination thereof.

Another aspect provides an article comprising:

(a) a substrate having a first major surface; and

(b) a deposit of a paste composition on a preselected portion of the first major surface of the substrate, wherein the paste composition comprises in admixture:
(i) about 75% to about 99% by weight based on solids of a source of an electrically conductive metal;
(ii) about 0.1% to about 10% by weight based on solids of a glass component; and
(iii) 0 to about 15% by weight based on solids of an optional zinc-containing additive that is at least one of zinc oxide, a compound that can generate zinc oxide upon firing, metallic zinc, a zinc alloy, or a mixture thereof, and
(iv) an organic medium in which the components (i) through (iii) are dispersed,
the organic medium comprising about 0.01 to about 10% by weight based on total composition of a surfactant having a formula

(R1)(R2)(R3)(R4)N⁺X⁻,
wherein each of R1, R2, R3, R4 is separately an alkyl, alkyl/aryl, alkyl/heteroaryl, or polyethylene glycol group, at least one of R1, R2, R3, or R4 is a polyethylene glycol or oleyl amide group, and X⁻ is a halide, alkylsulfonate, alkylsulfate, alkylphosphate, alkylcarboxylate, arylcarboxylate, dodecylbenzenesulfonate, dicyanamide, bis(2,4,4-trimethylpentyl)phosphinate, dibutyl phosphate, hexafluorophosphate, or a combination thereof.

Still another aspect provides a process comprising:

(a) providing a substrate having a first major surface;

(b) applying a paste composition onto a preselected portion of the first major surface, wherein the paste composition comprises in admixture:
i) about 80 to about 99% by weight based on solids of a source of an electrically conductive metal;
ii) about 0.1 to about 10% by weight based on solids of a glass component;
iii) 0 to about 15% by weight based on solids of an optional zinc-containing additive, that is at least one of zinc oxide, a compound that generates zinc oxide upon firing, metallic zinc, a zinc alloy, or a mixture thereof, and
iv) an organic medium in which the components i) through iii) are dispersed, the organic medium comprising about 0.01 to about 10% by weight based on total composition of a surfactant having a formula

(R1)(R2)(R3)(R4)N⁺X⁻,
wherein each of R1, R2, R3, R4 is separately an alkyl, alkyl/aryl, alkyl/heteroaryl, or polyethylene glycol group, at least one of R1, R2, R3, or R4 is a polyethylene glycol or oleyl amide group, and X⁻ is a halide, alkylsulfonate, alkylsulfate, alkylphosphate, alkylcarboxylate, arylcarboxylate, dodecylbenzenesulfonate, dicyanamide, bis(2,4,4-trimethylpentyl)phosphinate, dibutyl phosphate, hexafluorophosphate, or a combination thereof, and

(c) firing the substrate and the paste composition, whereby the organic medium of the paste composition is removed and an electrode is formed that has electrical contact with the substrate.

In implementations of the foregoing article and process, the substrate may be a semiconductor, including without limitation a silicon wafer, which optionally has an insulating layer on its major surface, and the present paste composition is applied over the insulating layer. In an embodiment, the paste composition facilitates removal of the insulating layer so that a mechanically and electrically robust contact is established between the underlying semiconductor and the conductive structure being formed.

Among the devices that may be formed using the present process are photovoltaic cells and arrays thereof.

### BRIEF DESCRIPTION OF THE DRAWINGS

The invention will be more fully understood and further advantages will become apparent when reference is had to the following detailed description of the preferred embodiments of the invention and the accompanying drawings, wherein like reference numeral denote similar elements throughout the several views and in which:

FIGS. 1A-1F depict successive steps of a process by which a semiconductor device may be fabricated. The device in turn may be incorporated into a photovoltaic cell. Reference numerals as used in FIGS. 1A-1F include the following:

10: p-type substrate

12: first major surface (front side) of substrate 10

14: second major surface (back side) of substrate 10

20: n-type diffusion layer

30: insulating layer

40: p+ layer

60: aluminum paste formed on back side

61: aluminum back electrode (obtained by firing back side aluminum paste)

70: silver or silver/aluminum paste formed on back side

71: silver or silver/aluminum back electrode (obtained by firing back side silver paste)

500: silver paste formed on front side according to the invention

501: silver front electrode according to the invention (formed by firing front side silver paste)

### DETAILED DESCRIPTION OF THE INVENTION

Solar-powered photovoltaic (PV) systems are considered to be environmentally beneficial in that they reduce the need for fossil fuels. The present invention addresses the need for a process to manufacture high performance semiconductor devices having mechanically robust, high conductivity electrodes. In an aspect of the present disclosure, there is provided a conductive paste composition that is beneficially employed in the fabrication of front-side electrodes of photovoltaic devices, which must make good electrical contact despite the presence of a front-side insulating layer typically included.

An embodiment of the present invention relates to conductive paste compositions. In an aspect of the embodiment, the paste composition may include a conductive metal powder and a glass component such as a glass frit, which are dispersed in an organic medium that includes a surfactant. The paste composition optionally includes a discrete, zinc-containing additive and/or other components.

In an aspect, the present invention provides a paste composition that comprises: a functional conductive component, such as a source of an electrically conductive metal; a glass component; an optional discrete, Zn-containing additive; and an organic medium, in which the other components are dispersed.

As further described below, the paste composition also comprises an organic medium, which acts as a carrier or vehicle for the inorganic constituents, which are dispersed therein. The paste composition includes a surfactant and may also include additional components such as thickeners, thixotropes and binders.

As would be recognized by a skilled artisan, the paste composition described herein can be termed “conductive,” meaning that the composition can be formed into a structure and thereafter processed to exhibit an electrical conductivity sufficient for conducting electrical current between devices or circuitry connected thereto.

For example, the paste composition can be used to form a conductive electrode employed in an electrical or electronic device such as a photovoltaic cell or an array of such cells. In an embodiment, the conductive electrode is disposed as the front side electrode of a photovoltaic cell. Ideally, a paste composition is chosen that promotes the formation of a relatively low resistance contact between the front side metallization and the underlying semiconductor substrate. Suitable paste compositions are believed to aid in etching surface insulating layers often employed in semiconductor structures such as photovoltaic cells. This layer must be penetrated for a good electrical contact to be established.

Alternatively, the paste composition can be used to form a conductive structure that includes conductive traces, such as those employed in a semiconductor module that is to be incorporated into an electrical or electronic device.

### I. Inorganic Components

An embodiment of the present invention relates to a paste composition, which may include: an inorganic solids portion comprising a functional material providing electrical conductivity, a glass frit or flux material, an optional Zn-containing additive; and an organic medium or vehicle in which the inorganic solids are dispersed. The paste composition may further include additional components such as surfactants, thickeners, thixotropes and binders.

### A. Electrically Conductive Functional Materials

In an embodiment, the source of electrically conductive metal providing the functional conductive component in the present paste composition is an electrically conductive metal powder, which is incorporated directly as part of the inorganic solids of the composition. In another embodiment, a mixture of two or more such metals can be incorporated. Alternatively, the electrically conductive metal may be supplied by a metal oxide or salt that decomposes upon exposure to the heat of firing to form the metal. Exemplary metals include, without limitation, silver, gold, copper, nickel, palladium, and alloys and mixtures thereof. As used herein, the term “silver” is to be understood as referring to elemental silver metal, alloys of silver, and mixtures thereof, and may further include silver oxide (Ag₂O) or silver salts such as AgCl, AgNO₃, AgOOCCH₃ (silver acetate), AgOOCF₃ (silver trifluoroacetate), Ag₃PO₄ (silver orthophosphate), or mixtures thereof. Silver is preferred for its high conductivity and processability, but any material that affords a conductivity that is both sufficient to permit passage of an electric current and compatible with the other components of the paste composition also may be used.

Electrically conductive metal powder used in the present paste composition may be supplied as finely divided particles having any one or more of the following morphologies: a powder form, a flake form, a spherical form, a granular form, a nodular form, a crystalline form, other irregular forms, or mixtures thereof. The electrically conductive metal or source thereof may also be provided in a colloidal suspension, in which case the colloidal carrier would not be included in any calculation of weight percentages of the solids of which the colloidal material is part.

The particle size of the metal is not subject to any particular limitation. In various embodiments, the average particle size is greater than 0.2 μm and less than 10 μm, or the average particle size is greater than 0.4 μm and less than 5 μm. Particle sizes of the metal and other constituents of the composition described herein are measured using dynamic light scattering or laser diffraction, but other methods, such as microscopy, can also be used. Instruments for such measurements are available commercially, e.g. the Horiba Model LA-910 particle size analyzer, (Horiba Instruments Inc., Irvine, Calif.).

The electrically conductive material may comprise any of a variety of percentages of the composition of the paste composition. To attain high conductivity in a finished conductive structure, it is generally preferable to have the concentration of the electrically conductive material be as high as possible, while maintaining other required characteristics of the paste composition that relate to either processing or final use. In a non-limiting embodiment, the silver may be from about 75 to about 99% of the solid components of the thick film composition. In further embodiments, the silver may be from about 80 to about 85 wt %, about 85 to about 98 wt %, or about 92 to about 98 wt % of the solid components of the thick film composition. In an embodiment, the solids portion of the thick film composition may include about 80 to about 90 wt % silver particles and about 1 to about 9 wt % silver flakes. In an embodiment, the solids portion of the thick film composition may include about 75 to about 90 wt % silver particles and about 1 to about 9 wt % silver flakes. In another embodiment, the solids portion of the thick film composition may include about 75 to about 90 wt % silver flakes and about 1 to about 9 wt % of colloidal silver. In a further embodiment, the solids portion of the thick film composition may include about 60 to about 90 wt % of silver powder or silver flakes and about 0.1 to about 20 wt % of colloidal silver.

The electrically conductive metal used herein, particularly when in powder form, may be coated or uncoated; for example, it may be at least partially coated with a surfactant to facilitate processing. Suitable coating surfactants include, for example, stearic acid, palmitic acid, a salt of stearate, a salt of palmitate, and mixtures thereof. Other surfactants that also may be utilized include lauric acid, oleic acid, capric acid, myristic acid, linoleic acid, and mixtures thereof. Still other surfactants that also may be utilized include polyethylene oxide, polyethylene glycol, benzotriazole, poly(ethylene glycol)acetic acid and other similar organic molecules. A suitable counter ion for use in a coating surfactant includes without limitation hydrogen, ammonium, sodium, potassium, and mixtures thereof. When the electrically conductive metal is silver, it may be coated, for example, with a phosphorus-containing compound. As discussed further below, surfactant may be provided as part of the organic medium as an alternative, or in addition to that supplied via coating of the metal particles.

As further described below, the electrically conductive metal can be dispersed in an organic medium that acts as a carrier for the metal phase and other constituents present in the formulation.

### B. Glass Component

The present paste composition includes a glass component, such as a glass frit. In some embodiments, the composition and the glass component thereof are lead-free. As used herein, the term “lead-free” refers to a composition to which no lead has been specifically added, and in which the amount of lead present as a trace component or impurity is less than 1000 parts per million (ppm). In another embodiment, the amount of lead present as a trace component or impurity is less than 1000 parts per million (ppm), or less than 300 ppm, or less than 100 ppm. In certain embodiments, addition of other elements, including Cd and Ni, is specifically excluded. In an embodiment, a lead-free composition may contain less than 1000 ppm of lead, and optionally, less than 1000 ppm of Cd and less than 1000 ppm of Ni as trace impurities; or less than 300 ppm of lead, less than 300 ppm of Cd, and less than 300 ppm of Ni; or less than 100 ppm of lead, less than 100 ppm of Cd, and less than 100 ppm of Ni.

In other embodiments of the present composition, a glass component containing lead may be used, for example a frit containing PbO and SiO₂ and optional amounts of other oxides including, without limitation, oxides of B, Bi, P, V, Ge, and the like. Lead oxide content in the frit can be as high 100 mol % and as low as 0.1 mol % of the total frit.

In an embodiment of the invention, the glass component of the paste composition may include one or more of three groups of constituents: glass formers, intermediate oxides, and modifiers. Exemplary glass formers may have a high bond coordination and smaller ionic size; the glass formers may form bridging covalent bonds when heated and quenched from a melt. Exemplary glass formers include, but are not limited to: SiO₂, B₂O₃, P₂O₅, V₂O₅, GeO₂, or the like. Exemplary intermediate oxides include, but are not limited to: TiO₂, Ta₂O₅, Nb₂O₅, ZrO₂, CeO₂, SnO₂, Al₂O₃, HfO₂, and the like. Intermediate oxides may be used to substitute glass formers, as recognized by one of skill in the art. Exemplary modifiers may have a more ionic nature, and may terminate bonds. The modifiers may affect specific properties; for example, modifiers may result in reduction of glass viscosity and/or modification of glass wetting properties, for example. Exemplary modifiers include, but are not limited to: oxides such as alkali metal oxides, alkaline earth oxides, PbO, CuO, CdO, ZnO, Bi₂O₃, Ag₂O, MoO₃, WO₃, and the like. Any other oxide known in the glass art may also be included.

In an embodiment, the glass component may be selected by one of skill in the art to assist in the at least partial penetration of oxide or nitride insulating layers during firing. As described herein, this at least partial penetration may lead to the formation of an effective electrical contact to the silicon surface of a photovoltaic device structure. The formulation components are not limited to glass forming materials.

An average particle size of the glass component may be in the range of 0.5-1.5 μm. In a further embodiment, an average particle size may be in the range of 0.8-1.2 μm. In an embodiment, the softening point of the glass frit (Ts: second transition point of DTA) is in the range of 300-600° C. In an embodiment, the amount of glass frit in the total composition may be in the range of 0.5 to 4 wt. % of the total composition. In one embodiment, the glass composition is present in the amount of 1 to 10 weight percent total composition. In a further embodiment, the glass composition is present in the range of 1.5 to 5.0 weight percent total composition.

The glasses described herein may be produced by conventional glass making techniques. In an implementation, the glass component may be prepared in 500-1000 gram quantities. The ingredients may be weighed and mixed in the desired proportions and heated in platinum alloy crucibles in a suitable furnace to form a melt. Heating may be conducted to a peak temperature (1000° C.-1200° C.) and for a time such that the melt becomes entirely liquid and homogeneous. Thereafter, the molten glass is quenched and comminuted to provide the desired particle size. In an embodiment, the glass material is supplied as a powder with its 50% volume distribution (d₅₀) size between 1 and 3 μm. Alternative synthesis techniques may also be used for making the glass components useful in the present paste composition. These techniques include, but are not limited to, water quenching, sol-gel, spray pyrolysis, or others appropriate for making powder forms of glass.

### Flux Materials

An embodiment of the present invention relates to a paste composition, and to structures and devices made therewith, wherein the glass component includes a flux material. The flux material, in an embodiment, may have properties similar to those of other portions of the glass component, such as possessing lower softening characteristics. For example, oxide or halogen compounds may be used. The compounds may assist penetration of an insulating layer in the structures described herein. Non-limiting examples of such compounds include materials that have been coated or,encased in an organic or inorganic barrier coating to protect against adverse reactions with organic binder components of the paste medium. Non-limiting examples of such flux materials may include PbF₂, BiF₃, V₂O₅, alkali metal oxides and the like.

### Glass Blending

In an embodiment, one or more glass frit materials may be present as the glass component of the present paste composition. In an embodiment, a first glass frit material may be selected by one of skill in the art for its capability to rapidly digest the insulating layer; further the glass frit material may have strong corrosive power and low viscosity.

In an embodiment, a second glass frit material may be designed to slowly blend with the first glass frit material while retarding the chemical activity. A stopping condition may result which may effect the partial removal of the insulating layer but without attacking the underlying emitter diffused region potentially shunting the device is the corrosive action proceeds unchecked. Such a glass frit material may be characterized as having a sufficiently higher viscosity to provide a stable manufacturing window to remove insulating layers without damage to the diffused p-n junction region of the semiconductor substrate.

In a non-limiting, exemplary admixture, the first glass frit material may be SiO₂ 1.7 wt %, ZrO₂ 0.5 wt %, B₂O₃ 12 wt % , Na₂O 0.4 wt %, Li₂O 0.8 wt %, and Bi₂O₃ 84.6 wt % and the second glass frit material may be SiO₂ 27 wt %, ZrO₂ 4.1 wt %, Bi₂O₃ 68.9 wt %. The proportions of the two frit materials may be chosen to improve the performance of the paste composition, under conditions recognized by one of skill in the art.

The skilled person will further recognize that or other oxides or fluorides and small impurities may be present in the glass component without materially affecting the ability of the paste composition to form a high-quality electrode, including an electrode in contact with a semiconductor substrate.

### C. Zinc-Containing Additive

In an embodiment, the present paste composition optionally comprises a zinc-containing additive. The zinc additive is at least one of metallic zinc, a zinc alloy, zinc oxide, a compound that generates zinc oxide upon firing, or a mixture thereof. In an embodiment, the paste composition comprises about 0.1 to about 15%, or about 0.1 to about 8%, or about 0.5 to about 5% by weight based on solids of the Zn-containing additive. In an embodiment, some or all of the Zn-containing additive is ZnO.

In an embodiment, the particle size of the optional Zn-containing additive is not subject to any particular limitation. In an embodiment, the particle size of the additive may be in the range of 1.0 nanometers (nm) to 150 μm.

### II. Organic Medium

The inorganic components of the present composition are typically mixed with an organic vehicle to form a relatively viscous material referred to as a “paste” or an “ink” that has a consistency and rheology that render it suitable for printing processes, including without limitation screen printing. The mixing is typically done with a mechanical system, and the constituents may be combined in any order, as long as they are uniformly dispersed and the final formulation has characteristics such that it can be successfully applied during end use.

A wide variety of inert viscous materials can be admixed in an organic medium in the present composition including, without limitation, an inert, non-aqueous liquid that may or may not contain thickeners or stabilizers. By “inert” is meant a material that may be removed by a firing operation without leaving any substantial residue or other adverse effect that is detrimental to final conductor line properties.

The proportions of organic vehicle and inorganic components in the present paste composition can vary in accordance with the method of applying the paste and the kind of organic vehicle used. Usually, the dispersion will contain 70 to 99 wt. %, or 85 to 95 wt. %, of inorganic components and 1 to 30 wt. %, or 2 to 20 wt. %, or 1 to 10 wt. %, of organic vehicle.

The organic medium typically provides a vehicle in which the inorganic components are dispersible with a good degree of stability. In particular, the composition preferably has a stability compatible not only with the requisite manufacturing, shipping, and storage, but also with conditions encountered during deposition, e.g. by a screen printing process. Ideally, the rheological properties of the medium are such that it lends good application properties to the composition, including stable and uniform dispersion of solids, appropriate viscosity and thixotropy for screen printing, appropriate wettability of the paste solids and the substrate on which printing will occur, a rapid drying rate after deposition, and stable firing properties.

Substances useful in the formulation of the organic medium of the present paste composition include, without limitation, ones disclosed in U.S. Pat. No. 7,494,607, such as ethylhydroxyethyl cellulose, wood rosin and derivatives thereof, mixtures of ethyl cellulose and phenolic resins, cellulose acetate, cellulose acetate butyrate, polymethacrylates of lower alcohols, monobutyl ether of ethylene glycol, monoacetate ester alcohols, and terpenes such as alpha- or beta-terpineol or mixtures thereof with other solvents such as kerosene, dibutylphthalate, butyl carbitol, butyl carbitol acetate, hexylene glycol and high-boiling alcohols and alcohol esters. A preferred ester alcohol is the monoisobutyrate of 2,2,4-trimethyl-1,3-pentanediol, which is available commercially from Eastman Chemical (Kingsport, Tenn.) as Texanol®.

A polymer frequently used in printable conductive metal pastes is ethyl cellulose. Other exemplary polymers that may be used include ethylhydroxyethyl cellulose, wood rosin and derivatives thereof, mixtures of ethyl cellulose and phenolic resins, cellulose acetate, cellulose acetate butyrate, poly(methacrylate)s of lower alcohols, and monoalkyl ethers of ethylene glycol monoacetate.

The viscosity of a polymer such as ethyl cellulose typically increases with its average molecular weight. The present paste composition may be adjusted to provide a viscosity suitable for screen printing, e.g., by adding a suitable amount of one or more solvent(s).

Any of these polymers may be dissolved in a suitable solvent, including those described herein. In an embodiment, the organic medium comprises about 2 wt. % to about 11 wt. % of one or more polymers. The polymer comprises about 0.1 wt. % to about 5 wt. % of the total paste composition.

Some embodiments may also incorporate volatile liquids in the organic medium to promote rapid hardening after application on the substrate. Various combinations of these and other solvents are formulated to provide the desired viscosity and volatility.

In an embodiment, the organic medium may include one or more components selected from the group consisting of: bis(2-(2butoxyethoxy)ethyl)adipate, dibasic ester, octyl epoxy tallate (DRAPEX® 4.4 from Witco Chemical), Oxocol (isotetradecanol made by Nissan Chemical), and FORALYN™ 110 (pentaerythritol ester of hydrogenated rosin from Eastman Chemical BV). The paste compositions may also include additional additives or components.

The dibasic ester useful in the present paste composition may comprise one or more dimethyl ester selected from the group consisting of dimethyl ester of adipic acid, dimethyl ester of glutaric acid, and dimethyl ester of succinic acid. Various forms of such materials containing different proportions of the dimethyl esters are available under the DBE® trade name from Invista (Wilmington, Del.). For the present paste composition, a preferred version is sold as DBE-3 and is said by the manufacturer to contain 85-95 weight percent dimethyl adipate, 5-15 weight percent dimethyl glutarate, and 0-1.0 weight percent dimethyl succinate based on total weight of dibasic ester.

Further ingredients optionally may be incorporated in the organic vehicle, such as thickeners, stabilizers, and/or other common additives known to those skilled in the art. The organic vehicle may be a solution of one or more polymers in a solvent. Additionally, effective amounts of additives, such as surfactants or wetting agents, may be a part of the organic vehicle. Such added surfactant may be included in the organic vehicle in addition to any surfactant included as a coating on the conductive metal powder of the paste composition. Suitable wetting agents include phosphate esters and soya lecithin. Both inorganic and organic thixotropes may also be present.

Among the commonly used organic thixotropic agents are hydrogenated castor oil and derivatives thereof, but other suitable agents may be used instead of, or in addition to, these substances. It is, of course, not always necessary to incorporate a thixotropic agent since the solvent and resin properties coupled with the shear thinning inherent in any suspension may alone be suitable in this regard.

In an embodiment, the organic medium includes about 0.01 to about 10% by weight of a surfactant having the general structure:

(R1)(R2)(R3)(R4)N⁺X⁻

wherein each of R1, R2, R3, R4 is separately an alkyl, alkyl/aryl or heteroaryl, or polyethylene glycol group, with at least one of R1, R2, R3, and R4 being a polyethylene glycol or oleyl amide group. In various embodiments, each of groups R1, R2, R3, and R4 contains 1 to 40 carbon atoms in chains or rings. One or more of the groups optionally includes a ring with one or two nitrogen atoms. In other embodiments, each of R1, R2, R3, and R4 contains 2 to 25 carbon atoms or 4 to 20 carbon atoms in chains or rings. Each of R1, R2, R3, and R4 is independently chosen and could be the same or different. X⁻ is a halide, alkylsulfonate, alkylsulfate, alkylphosphate, alkylcarboxylate, arylcarboxylate, dodecylbenzenesulfonate, dicyanamide, bis(2,4,4-trimethylpentyl)phosphinate, dibutyl phosphate, hexafluorophosphate, or a combination thereof.

Representative surfactant formulations having the foregoing structure as the predominant ingredient and found useful in formulating the present paste composition are commercially available from Evonik Goldschmidt Corporation, Hopewell, Va., under the trade name TEGO®. Suitable TEGO® surfactants include Tego IL 36 ES, Tego IL T-16 ES, Tego IL K5 MS, Tego IL P 54 A, and Tego IL P 51 P.

Tego IL K5 MS is understood to comprise a quaternary ammonium compound, i.e. coco alkylbis(hydroxyethyl)methyl, ethoxylated, methyl sulfate (CAS-No 68989-03-07) in concentration between 98 to 100%. Optionally, it may further contain one or more of oxirane (CAS-No 75-21-8) in concentration below 0.003% and sulfuric acid and dimethyl ester (CAS-No 77-78-1) in concentration below 0.02%.

Tego IL P 54 A is understood to comprise an alkoxylated ammonium acetate in concentration between 90% and 99%. Optionally, it may further contain one or more of 1,2-ethanediol (CAS-No. 107-21-1) in concentration between 1 and 10%, (CAS-No 75-21-8) in concentration below 0.001%, and methyl oxirane (CAS-No 75-56-9) in concentration below 0.001%.

Tego IL P 51 P is understood to comprise an alkoxylated ammonium phosphate in concentration between 90 and 99%. Optionally, it may further contain 1,2-ethanediol (CAS-No. 107-21-1) in concentration between 1 and 10%.

Tego IL T16 ES is understood to comprise as its main ingredient a substance having the following general formula:

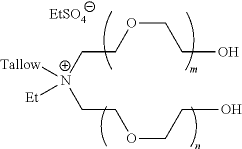

In an embodiment, the present paste may incorporate a surfactant having this structure wherein the values of m and n range from 6 to 20.

Tego IL 36 ES is understood to comprise as its main ingredient a substance having the following general formula that includes an oleyl amide and a two-nitrogen ring:

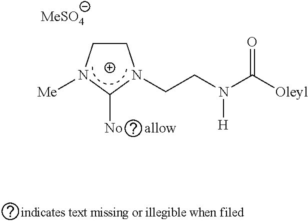

### III. Application and Processing

Various embodiments of the present disclosure relate to conductive structures formed using the present paste composition, devices including such structures, and related manufacturing methods.

As noted above, conductive structures such as electrodes and other conductive traces are commonly formed by screen-printing the paste composition onto a substrate, although other forms of printing, such as plating, extrusion, inkjet, shaped or multiple printing, or ribbons, may also be used. After deposition, the composition is fired at an elevated temperature, which causes the conductive metal to sinter and to bond to the substrate, thereby forming the desired conductive structure.

For example, the present composition can be applied on a preselected portion of a substrate in a variety of different configurations or patterns. The substrate may be, without limitation, a semiconductor such as a thin single-crystal or multi-crystalline silicon wafer having first and second major surfaces on its opposite large sides; the substrate is preferably a junction-bearing substrate. Alternatively, the preselected portion may cover substantially all of a major surface of the substrate. The electrode is formed by depositing the paste on the substrate in a preselected pattern, drying the paste, and thereafter firing the deposited, dried paste.

Conductors formed by printing and firing a paste such as that provided herein are often denominated as “thick film” conductors, since they are ordinarily substantially thicker than traces formed by atomistic processes, such as those used in fabricating integrated circuits. For example, thick film conductors may have a thickness after firing of about 1 to 100 μm. Consequently, paste compositions that in their processed form provide conductivity and are suitably used for printing processes are often called “thick film pastes” or “conductive inks.”

The present paste composition may be printed on the substrate in any useful pattern. If the substrate includes an insulating surface layer, the composition may be printed atop the layer. For example, the electrode pattern used for the front-side of a photovoltaic cell commonly includes a plurality of narrow grid lines connected to one or more bus bars. In an embodiment, such grid lines might be 40 to 150 μm wide and 10 to 30 μm thick and spaced by 2 to 3 mm on center. Ideally, the features of the electrode pattern should be well defined and have high electrical conductivity and low contact resistance with the underlying structure.

The TEGO surfactants discussed above have been found to function well as components in printable paste compositions. In an embodiment, paste compositions comprising these materials as surfactants generally exhibit rheological characteristics that result in excellent printability and a resulting conductive structure that is electrically and mechanically robust. Compared to surfactants typically used in conventional front-side pastes, the present surfactants are believed to promote a highly homogeneous dispersion of the solid components, including the conductive metal powder and glass component, in the paste composition. The dispersion, in turn, permits uniform traces to be screen printed, even the relatively small grid lines used in a typical photovoltaic cell front side. The firing operation then results in electrodes that have high conductivity and good adhesion to the substrate, which are believed to be promoted by the absence of regions in which there is an excess or deficiency of either the glass component or the conductive metal powder.

### Firing

A firing operation may be used in the present process to effect a substantially complete burnout of the organic medium from the deposited paste, which typically involves volatilization and/or pyrolysis of the organic materials. A drying operation optionally precedes the firing operation, and is carried out at a modest temperature to harden the paste composition by removing its most volatile organics.

The firing process removes the organic medium, sinters the conductive metal in the composition, and establishes electrical contact between the semiconductor substrate and the fired conductive metal. Firing may be performed in an atmosphere composed of air, nitrogen, an inert gas, or an oxygen-containing mixture such as a mixed gas of oxygen and nitrogen. In an embodiment, the organic medium may include one or more components that burn out at temperatures above 400° C., or, in a further embodiment, above 500° C.

In an embodiment, the burn-out temperature for the firing may in the range between about 300° C. to about 1000° C., or about 300° C. to about 525° C., or about 300° C. to about 650° C., or about 650° C. to about 1000° C. The firing may be conducted using any suitable heat source. In an embodiment, the firing is accomplished by passing the substrate bearing the printed paste composition pattern through a belt furnace at high transport rates, for example between about 100 to about 500 centimeters per minute, with resulting hold-up times between about 0.05 to about 5 minutes. Multiple temperature zones may be used to control the desired thermal profile, and the number of zones may vary, for example, between 3 to 11 zones. The temperature of a burn-out operation conducted using a belt furnace is conventionally specified by the furnace set point in the hottest zone of the furnace, but it is known that the peak temperature attained by the passing substrate in such a process is somewhat lower than the highest set point. Use of other batch and continuous rapid fire furnace designs known to one of skill in the art are also contemplated.

In some photovoltaic cell embodiments, the backside electrode is provided by a metallization also formed by firing a paste composition deposited onto the cell backside. Typically, a singe firing operation is used to accomplish formation of both front and back side conductive structures.

### IV. Structures

An embodiment of the present disclosure relates to an article of manufacture comprising a conductive electrode structure formed using the present paste composition on a substrate, which may be a semiconductor substrate. In certain embodiments, the article may be employed in a photovoltaic device, a solar cell, or a solar panel containing a plurality of such devices. Such devices may include one or both of a frontside and a back side electrode made using the present paste composition.

### Insulating Films

In some embodiments, an insulating layer may be present on one or more of the substrate's major surfaces. The layer may comprise one or more components selected from aluminum oxide, titanium oxide, silicon nitride, SiNx:H (silicon nitride containing hydrogen for passivation during subsequent firing processing), silicon oxide, and silicon oxide/titanium oxide, and may be in the form of a single, homogeneous layer or multiple sequential sub-layers of any of these materials.

In some embodiments, the insulating layer provides the cell with an anti-reflective property, which lowers the reflectance of light incident on the cell's surface, thereby improving utilization of the incident light and increasing the electrical current the cell can generate. Thus, the insulating layer is often denoted as an anti-reflective coating (ARC). The composition and thickness of the layer are preferably chosen to maximize the antireflective property in accordance with the layer material's refractive index. In some embodiments, the deposition processing conditions are adjusted to vary the stoichiometry of the layer, thereby altering properties such as the refractive index to a desired value. For example, a thickness of about 700 to 900 Å (70 to 90 nm) is suitable for a silicon nitride layer with a refractive index of about 1.9 to 2.0.

In an embodiment, the insulating layer may be deposited on the substrate by methods known in the microelectronics art, such as any form of chemical vapor deposition (“CVD”) including plasma-enhanced CVD (“PECVD”) or thermal CVD, thermal oxidation, or sputtering. In another embodiment, the substrate is coated with a liquid material that under thermal treatment decomposes or reacts with the substrate to form the insulating layer. In still another embodiment, the substrate is thermally treated in the presence of an oxygen- or nitrogen-containing atmosphere to form an insulating layer. Alternatively, no insulating layer is specifically applied to the substrate, but a naturally forming substance, such as silicon oxide on a silicon wafer, may function as an insulating layer.

In various embodiments, a portion of any insulating layer present, whether specifically applied or naturally-occurring, may be removed to enhance electrical contact between the paste composition and the underlying semiconductor substrate. Preferably, the glass component and the optional additive act to at least partially dissolve the insulating layer to permit contact to be established.

While the present invention is not limited by any particular theory of operation, it is believed that, upon firing, the presence of a discrete, Zn-containing additive component in the present paste composition promotes etching of the insulating layer, which in turn permits the formation of a low resistance, front-side electrical contact between the metal(s) of the composition and the underlying substrate. It has been found that including the Zn-containing material as a discrete additive rather than as an admixed constituent of the glass component results in superior conductive structure performance.

The present method optionally includes the step of forming the insulating layer on the semiconductor substrate prior to the application of the paste composition.

### Semiconductor Device Manufacture

An embodiment of the present disclosure relates to a method of manufacturing an electronic or semiconductor device, including without limitation a photovoltaic cell or array of photovoltaic cells, that comprises conductive traces formed using the present paste composition.

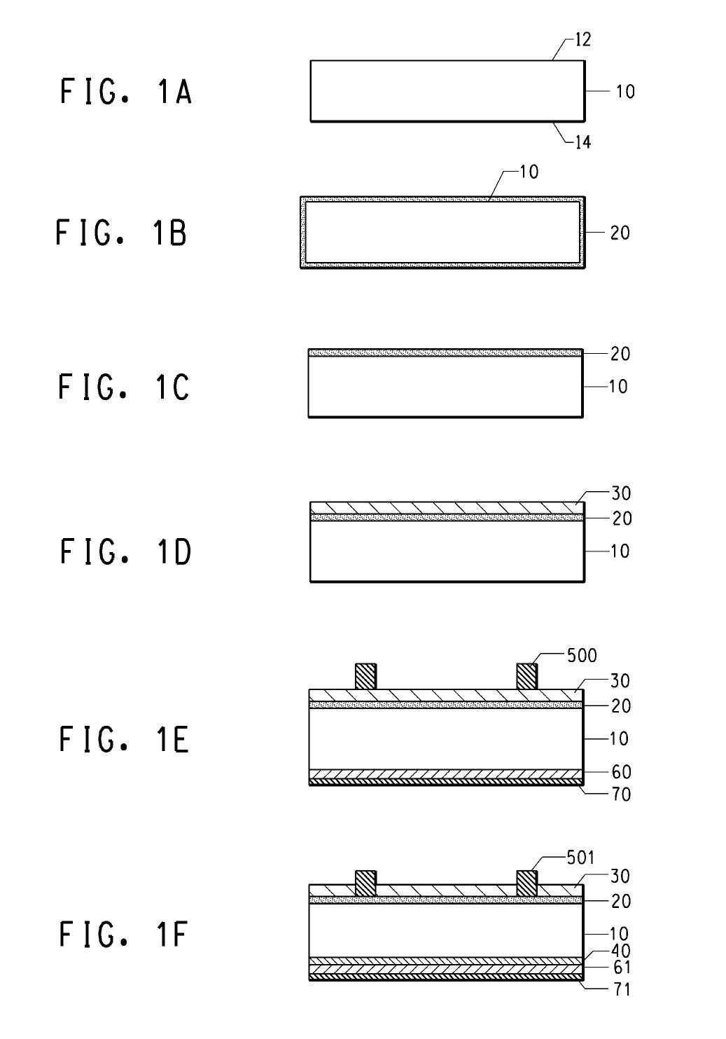

In an embodiment, the present process can be used to fabricate a photovoltaic cell. One possible sequence of steps for carrying out the manufacture is illustrated in FIG. 1.

FIG. 1(a) shows a p-type substrate 10, which may be a single crystal, multicrystalline, or polycrystalline silicon. Substrate 10 may be sliced, for example, from an ingot that has been formed from a pulling or casting process. Surface damage, e.g. from slicing with a wire saw, and contamination may be removed by etching away about 10 to 20 μm of the substrate surface using an aqueous alkali solution such as aqueous potassium hydroxide or aqueous sodium hydroxide, or using a mixture of hydrofluoric acid and nitric acid. In addition, a step in which the substrate is washed with a mixture of hydrochloric acid and hydrogen peroxide may be added to remove heavy metals such as iron adhering to the substrate surface. Substrate 10 may have a first major surface 12 that is textured to reduce light reflection. Texturing may be produced by etching a major surface with an aqueous alkali solution such as aqueous potassium hydroxide or aqueous sodium hydroxide.

In FIG. 1(b), an n-type diffusion layer 20 is formed to create a p-n junction with p-type material below. The n-type diffusion layer 20 can be formed by any suitable doping process, such as thermal diffusion of phosphorus (P) provided from phosphorus oxychloride (POCl3). In the absence of any particular modifications, the n-type diffusion layer 20 is formed over the entire surface of the silicon p-type substrate. The depth of the diffusion layer can be varied by controlling the diffusion temperature and time, and is generally formed in a thickness range of about 0.3 to 0.5 μm. The n-type diffusion layer may have a sheet resistivity from several tens of ohms per square up to about 120 ohms per square.

After protecting one surface of the n-type diffusion layer 20 with a resist or the like, the n-type diffusion layer 20 is removed from most surfaces by etching so that it remains only on the first major surface 12 of substrate 10, as shown in FIG. 1(c). The resist is then removed using an organic solvent or the like.

Next, as shown in FIG. 1(d), an insulating layer 30, which also functions as an antireflective coating, is formed on the n-type diffusion layer 20. The insulating layer is commonly silicon nitride, but can also be other a film of another material, such as SiNx:H (i.e., the insulating film comprises hydrogen for passivation during subsequent firing processing), titanium oxide, silicon oxide, mixed silicon oxide/titanium oxide, or aluminum oxide. The insulating layer can be in the form of a single layer or multiple layers.

Next, electrodes are formed on both major surfaces 12, 14 of the substrate. As shown in FIG. 1(e), a paste composition 500 of this invention is screen-printed on the insulating layer 30 of the first major surface 12 and then dried. For a photovoltaic cell, paste composition 500 is typically applied in a predetermined pattern of conductive lines extending from one or more bus bars that occupy a predetermined portion of the surface. In addition, aluminum paste 60 and back-side silver paste 70 are screen-printed onto the back side (the second major surface 14 of the substrate) and successively dried. The screen printing operations may be carried out in any order. For the sake of production efficiency, all these pastes are typically processed by co-firing them at a temperature in the range of about 700° C. to about 975° C. for a period of from several seconds to several tens of minute in air or an oxygen-containing atmosphere. An infrared-heated belt furnace is conveniently used for high throughput.

As shown in FIG. 1(f), the firing causes the depicted paste composition 500 on the front-side to sinter and penetrate through the insulating layer 30, thereby achieving electrical contact with the n-type diffusion layer 20, a condition known as “fire through.” This fired-through state, i.e., the extent to which the paste melts and passes through the insulating layer 30, depends on the quality and thickness of the insulating layer 30, the composition of the paste, and on the firing conditions. Firing thus converts paste 500 into electrode 501, as shown in FIG. 1(f).

The firing further causes aluminum to diffuse from the back-side aluminum paste into the silicon substrate, thereby forming a p+ layer 40, containing a high concentration of aluminum dopant. This layer is generally called the back surface field (BSF) layer, and helps to improve the energy conversion efficiency of the solar cell. Firing converts the dried aluminum paste 60 to an aluminum back electrode 61. The back-side silver paste 70 is fired at the same time, becoming a silver or silver/aluminum back electrode 71. During firing, the boundary between the back-side aluminum and the back-side silver assumes the state of an alloy, thereby achieving electrical connection. Most areas of the back electrode are occupied by the aluminum electrode, owing in part to the need to form a p+ layer 40. Since there is no need for incoming light to penetrate the back side, substantially the entire surface may be covered. At the same time, because soldering to an aluminum electrode is unfeasible, a silver or silver/aluminum back electrode is formed on limited areas of the backside as an electrode to permit soldered attachment of interconnecting copper ribbon or the like.

In an embodiment, the method of manufacture of the semiconductor device may also be characterized by manufacturing a semiconductor device from a structural element composed of a junction-bearing semiconductor substrate and an insulating film formed on one main surface thereof, wherein the insulating layer is selected from a titanium oxide silicon nitride, SiNx:H, silicon oxide, and silicon oxide/titanium oxide film, which method includes the steps of forming on the insulating film, in a predetermined shape and at a predetermined position, a metal paste material having the ability to react and penetrate the insulating film, forming electrical contact with the silicon substrate. An embodiment of the invention also provides a semiconductor device manufactured from this same method.

In an embodiment of the invention, the electrode formed from the conductive thick film composition(s) of the present invention may be fired in an atmosphere composed of a mixed gas of oxygen and nitrogen. This firing process removes the organic medium and sinters the glass frit with the Ag powder in the conductive thick film composition. The semiconductor substrate may be single-crystal or multicrystalline silicon, for example.

In an alternative embodiment in FIG. 1(d), a titanium oxide film may be formed on the n-type diffusion layer, 20, instead of the silicon nitride film, 30, functioning as an antireflection coating. The titanium oxide film is formed by coating a titanium-containing organic liquid material onto the n-type diffusion layer, 20, and firing, or by thermal CVD. It is also possible, in FIG. 1(d), to form a silicon oxide film on the n-type diffusion layer, 20, instead of the silicon nitride film 30 functioning as an antireflection layer. The silicon oxide film is formed by thermal oxidation, thermal CVD or plasma CVD.

The following examples are presented to provide a more complete understanding of the invention. The specific techniques, conditions, materials, proportions and reported data set forth to illustrate the principles and practice of the invention are exemplary and should not be construed as limiting the scope of the invention.

### EXAMPLES

### Materials

Materials used in formulating the paste compositions of the Examples included the following, which were obtained from commercial sources as indicated:
TEGO surfactants (Tego IL 36 ES, Tego IL T-16 ES, Tego IL K5 MS, Tego IL P 54 A, Tego IL P 51 P): Evonik Goldschmidt Corporation Hopewell, Va.;
Zinc oxide, particle size distribution in the range 0.5-10 μm, with 90% of the particles having a size (D₉₀) <1 μm: Horsehead Holding Corp., Pittsburgh, Pa.;
Ethyl cellulose: Ashland Chemical Company, Covington, Ky.;
TEXANOL™ ester alcohol (CAS No. 25265-77-4): (Eastman, Kingsport, Tenn.;
FORALYN™ 110 hydrogenated rosin resin: Eastman, Kingsport, Tenn.;
THIXATROL® ST modified castor oil derivative rheological additive: Elementis, Hightstown, N.J.;
DBE-3 dibasic ester: Invista, Wilmington, Del.

### Examples 1-5

### Paste Preparation

Paste compositions for Examples 1-5 of the present disclosure and Comparative Example 1 (“CE1”) were prepared using the following procedure, with the proportions of the constituents as set forth in Table I. First, the inorganic components were mixed together. To begin, the requisite amount of glass frit was added to zinc oxide in a mixing jar and mixed using a Thinky mixer (Thinky USA, Inc, Laguna Hills, Calif.) to produce a homogeneous combination. Then silver powder was added. Since the silver powder was the predominant inorganic component, it was added incrementally to promote thorough and uniform mixing.

The glass frit used in each of Examples 1-5 had the following composition in weight %: SiO₂: 22.0779%; Al₂O₃: 0.3840%; PbO: 46.6796%; B₂O₃: 7.4874%; Bi₂O₃: 6.7922; TiO₂: 5.8569%; PbF₂: 10.7220%. It was milled to a median particle size (d₅₀) in the range of 0.5-0.7 μm prior to use. The silver powder used had a predominantly spherical particle shape and a size distribution wherein d₉₀ was about 3.75 μm as measured using a Horiba LA-310 analyzer.

Then the organics were separately mixed. To begin, an ethyl cellulose solution was prepared using two grades of ethyl cellulose having different viscosities, resulting from different average molecular weights. The first grade was specified by the manufacturer as having a nominal viscosity of about 80 to 105 Pa-s, and the second grade had nominal viscosity of about 8 to 11 Pa-s, with each viscosity determined as that of a 5% solution of the ethyl cellulose in an 80/20 mixture of toluene/ethanol.

In the present examples, each of the ethyl cellulose grades was first dissolved in a suitable amount of TEXANOL™ ester alcohol (CAS No. 25265-77-4) solvent. These solutions were then combined. The amount of each grade and the TEXANOL™ solvent dilution used were adjusted to obtain a medium ultimately affording a viscosity suitable for screen printing.

Then requisite amounts of the following constituents were added in succession: FORALYN™ 110 resin; surfactant; THIXATROL® ST rheological additive; and DBE-3 dibasic ester. Examples 1-5 were prepared with various commercial versions of TEGO® surfactant as shown. Comparative Example 1 (“CE1”) was formulated with DUOMEEN® TDO (tallowpropylenediamine dioleate) surfactant, which is available from AkzoNobel Surface Chemistry (Chicago, Ill.). In each case, a suitable small portion of the solvent was held back, to be added at the end to adjust the final viscosity to a level permitting the composition to be screen printed onto a substrate. Typically, a final paste composition having a viscosity of about 300 Pa-s was found to yield good screen printing results, but some variation, for example ±50 Pa-s or more would be acceptable, depending on the precise printing parameters. After all the other organic ingredients were added, the mixture was Thinky-mixed for thirty seconds.

Thereafter, the mixed inorganic components were added to the mixed organics in three equal aliquots and Thinky-mixed for thirty seconds after each addition.

After being well mixed in the Thinky mixer, the paste composition was repeatedly passed through a 3-roll mill at progressively increasing pressures from 0 to 400 psi (2.75 MPa). The gap of the rolls was adjusted to 1 mil (25 μm). The viscosity of the paste after milling was adjusted as needed by adding small amounts of TEXANOL or other suitable solvent. The degree of dispersion was measured using commercial fineness of grind (FOG) gages (Precision Gage and Tool, Dayton, Ohio), in accordance with ASTM Standard Test Method D 1210-05, which is promulgated by ASTM International, West Conshohocken, Pa., and is incorporated herein by reference. The FOG value may be equal to or less than about 20/10 for paste compositions, meaning that the size of the largest particle detected is 20 μm and the median size is 10 μm.

TABLE I
Paste Compositions Containing TEGO ® Surfactants and Comparative Example

| | | | | Ethyl | Ethyl | FORALYN | | Surfactant | | | Solvent |
|---|---|---|---|---|---|---|---|---|---|---|---|
| | ZnO | Frit | Ag | Cellulose 1 | Cellulose 2 | 110 | TEGO ® | Amount | THIXATROL | DBE-3 | Holdback |
| Example | (g) | (g) | (g) | (g) | (g) | (g) | Surfactant | (g) | (g) | (g) | (g) |
| 1 | 2.0 | 0.8 | 32.4 | 0.52 | 0.20 | 1.0 | IL 36 ES | 0.4 | 0.2 | 1.4 | 1.08 |
| 2 | 2.0 | 0.8 | 32.4 | 0.52 | 0.20 | 1.0 | IL T16 ES | 0.4 | 0.2 | 1.4 | 1.08 |
| 3 | 1.4 | 0.56 | 22.7 | 0.36 | 0.14 | 0.56 | IL K5 MS | 0.7 | 0.14 | 0.98 | 0.48 |
| 4 | 1.4 | 0.56 | 22.7 | 0.36 | 0.14 | 0.56 | IL P54 A | 0.7 | 0.14 | 0.98 | 0.48 |
| 5 | 1.4 | 0.56 | 22.7 | 0.36 | 0.14 | 0.56 | IL P51 P | 0.7 | 0.14 | 0.98 | 0.48 |
| CE1 | 1.4 | 0.56 | 22.7 | 0.36 | 0.14 | 0.56 | * | 0.7 | 0.14 | 0.98 | 0.48 |

* DUOMEEN ® TDO (tallowpropylenediamine dioleate) surfactant

### Example 6

### PV Cell Manufacture

The paste compositions prepared as Examples 1-5 and Comparative Example 1 were used to prepare photovoltaic cells. For each of the compositions, front-side conductive structures comprising a pattern of thin lines connected to a bus bar were screen printed onto 65 ohm/sq, 200 μm thick silicon wafers (Q-Cells SE, 06766 Bitterfeld-Wolfen, Germany). A layer of SOLAMET® PV381 aluminum-based conductive paste composition (Dupont, Wilmington, Del.) was applied to the back side of each cell to be formed into the backside electrode using the same firing as the front side.

A total of 20 wafers were printed for each composition of Examples 1-5 and Comparative Example 1. All the wafers were fired at a series of four temperatures ranging from 800 to 950° C., five wafers for each composition and each temperature.

### Example 7

### Electrical Testing

The electrical performance of the photovoltaic cells prepared as set forth in Example 6 above was measured using an ST-1000 IV tester (Telecom STV Co., Moscow, Russia) at 25° C. ±1.0° C. The Xe arc lamp in the IV tester simulated sunlight with a known intensity and irradiated the front surface of the cell. The tester used a four contact method to measure current (I) and voltage (V) at approximately 400 load resistance settings to determine the cell's I-V curve. Fill factor (FF), series resistance (Ra) and efficiency (Eff) were calculated from the I-V curve for each cell. Means and medians of these quantities were calculated for the five cells of each test condition.

The electrical testing results are shown in Tables II and III, which respectively provide the mean and median values of FF, Eff, and Ra for cells having front-side electrode structures prepared with the various exemplary paste compositions and fired at 880° C., which was found to be approximately optimal.

TABLE II
Mean Performance of Photovoltaic Cells
at Optimal Firing Temperature

| | | | FF (%) | Eff (%) | Ra (Ω) |
|---|---|---|---|---|---|
| Example | TEGO ® Surfactant | Wt. % | (mean) | (mean) | (mean) |
| 1 | Tego IL 36 ES | 1 | 75.8 | 14.12 | 0.203 |
| 2 | Tego IL T16 ES | 1 | 76.3 | 14.25 | 0.193 |
| 3 | Tego IL K5 MS | 2.5 | 75.8 | 14.31 | 0.191 |
| 4 | Tego IL P54 A | 2.5 | 76.1 | 14.44 | 0.187 |
| 5 | Tego IL P51 P | 2.5 | 75.5 | 14.48 | 0.196 |
| CE1 | * | * | 76.2 | 14.36 | 0.189 |

* DUOMEEN ® TDO (tallowpropylenediamine dioleate) surfactant (2.5 wt. %)

TABLE III
Median Performance of Photovoltaic Cells
at Optimal Firing Temperature

| | TEGO ® | Wt. | FF (%) | Eff (%) | Ra (Ω) |
|---|---|---|---|---|---|
| Example | Surfactant | % | (median) | (median) | (median) |
| 1 | Tego IL 36 ES | 1 | 75.6 | 14.16 | 0.206 |
| 2 | Tego IL T16 ES | 1 | 76.4 | 14.3 | 0.192 |
| 3 | Tego IL K5 MS | 2.5 | 75.5 | 14.2 | 0.191 |
| 4 | Tego IL P54 A | 2.5 | 76.4 | 14.5 | 0.187 |
| 5 | Tego IL P51 P | 2.5 | 76.1 | 14.6 | 0.190 |
| CE1 | * | * | 76.7 | 14.5 | 0.187 |

* DUOMEEN ® TDO (tallowpropylenediamine dioleate) surfactant (2.5 wt. %)

The data of Tables II and III demonstrate that paste compositions including various TEGO® surfactants can be used to manufacture photocells having excellent electrical properties, including high efficiency, high form factor, and low resistance. The data compare favorably with results from Comparative Example 1, which employs a tallowpropylenediamine dioleate surfactant.

Having thus described the invention in rather full detail, it will be understood that this detail need not be strictly adhered to but that further changes and modifications may suggest themselves to one skilled in the art, all falling within the scope of the invention as defined by the subjoined claims

Where a range of numerical values is recited or established herein, the range includes the endpoints thereof and all the individual integers and fractions within the range, and also includes each of the narrower ranges therein formed by all the various possible combinations of those endpoints and internal integers and fractions to form subgroups of the larger group of values within the stated range to the same extent as if each of those narrower ranges was explicitly recited. Where a range of numerical values is stated herein as being greater than a stated value, the range is nevertheless finite and is bounded on its upper end by a value that is operable within the context of the invention as described herein. Where a range of numerical values is stated herein as being less than a stated value, the range is nevertheless bounded on its lower end by a non-zero value.

In this specification, unless explicitly stated otherwise or indicated to the contrary by the context of usage, where an embodiment of the subject matter hereof is stated or described as comprising, including, containing, having, being composed of, or being constituted by or of certain features or elements, one or more features or elements in addition to those explicitly stated or described may be present in the embodiment. An alternative embodiment of the subject matter hereof, however, may be stated or described as consisting essentially of certain features or elements, in which embodiment features or elements that would materially alter the principle of operation or the distinguishing characteristics of the embodiment are not present therein. A further alternative embodiment of the subject matter hereof may be stated or described as consisting of certain features or elements, in which embodiment, or in insubstantial variations thereof, only the features or elements specifically stated or described are present. Additionally, the term “comprising” is intended to include examples encompassed by the terms “consisting essentially of” and “consisting of.” Similarly, the term “consisting essentially of” is intended to include examples encompassed by the term “consisting of.”

When an amount, concentration, or other value or parameter is given as either a range, preferred range, or a list of upper preferable values and lower preferable values, this is to be understood as specifically disclosing all ranges formed from any pair of any upper range limit or preferred value and any lower range limit or preferred value, regardless of whether ranges are separately disclosed. Where a range of numerical values is recited herein, unless otherwise stated, the range is intended to include the endpoints thereof, and all integers and fractions within the range. It is not intended that the scope of the invention be limited to the specific values recited when defining a range

In this specification, unless explicitly stated otherwise or indicated to the contrary by the context of usage,

(a) amounts, sizes, ranges, formulations, parameters, and other quantities and characteristics recited herein, particularly when modified by the term “about”; may but need not be exact, and may also be approximate and/or larger or smaller (as desired) than stated, reflecting tolerances, conversion factors, rounding off, measurement error, and the like, as well as the inclusion within a stated value of those values outside it that have, within the context of this invention, functional and/or operable equivalence to the stated value; and

(b) all numerical quantities of parts, percentage, or ratio are given as parts, percentage, or ratio by weight; the stated parts, percentage, or ratio by weight may or may not add up to 100.

What is claimed is:

1. A paste composition comprising in admixture:
a) about 75 to about 99% by weight based on solids of a source of an electrically conductive metal;
b) about 0.1 to about 10% by weight based on solids of at least one glass component;
c) 0 to about 15% by weight based on solids of an optional zinc-containing additive that is at least one of zinc oxide, a compound that generates zinc oxide upon firing, zinc metal, a zinc alloy, or a mixture thereof; and
d) an organic medium in which the components a) through c) are dispersed, the organic medium comprising about 0.01 to about 10% by weight based on total composition of a surfactant having a formula:
(R1)(R2)(R3)(R4)N⁺X⁻,
wherein each of R1, R2, R3, and R4 is separately an alkyl, alkyl/aryl, alkyl/heteroaryl, or polyethylene glycol group, at least one of R1, R2, R3, or R4 is a polyethylene glycol or oleyl amide group, and X⁻ is a halide, alkylsulfonate, alkylsulfate, alkylphosphate, alkylcarboxylate, arylcarboxylate, dodecylbenzenesulfonate, dicyanamide, bis(2,4,4-trimethylpentyl)phosphinate, dibutyl phosphate, hexafluorophosphate, or a combination thereof.

2. The paste composition of claim 1, wherein each of the R1, R2, R3, and R4 groups contains 1 to 40 carbon atoms in chains or rings.

3. The paste composition of claim 2, wherein at least one of the R1, R2, R3, or R4 comprises a ring containing one or two nitrogen atoms.

4. The paste composition of claim 2, wherein each of the R1, R2, R3, and R4 groups contains from 2 to 25 carbon atoms in chains or rings.

5. The paste composition of claim 2, wherein each of the R1, R2, R3, and R4 groups contains from 4 to 20 carbon atoms in chains or rings.

6. The paste composition of claim 1, wherein the surfactant comprises a quaternary ammonium compound, coco alkylbis(hydroxyethyl)methyl, ethoxylated, methyl sulfate.

7. The paste composition of claim 1, wherein the surfactant comprises an alkoxylated ammonium acetate.

8. The paste composition of claim 1, wherein the surfactant comprises an alkoxylated ammonium phosphate and 1,2-ethanediol.

9. The paste composition of claim 1, wherein the surfactant comprises a substance having the formula

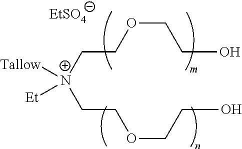

10. The paste composition of claim 1, wherein the surfactant comprises a substance having the formula

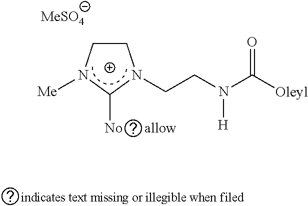

11. The paste composition of claim 1, comprising about 0.1 to about 15% by weight based on solids of the zinc-containing additive.

12. The paste composition of claim 11, wherein the zinc-containing additive comprises zinc oxide.

13. An article comprising:
(a) a substrate having a first major surface; and
(b) a deposit of a paste composition on a preselected portion of the first major surface of the substrate, wherein the paste composition comprises in admixture:
(i) about 75% to about 99% by weight based on solids of a source of an electrically conductive metal;
(ii) about 0.1% to about 10% by weight based on solids of a glass component; and
(iii) 0 to about 15% by weight based on solids of an optional zinc-containing additive that is at least one of zinc oxide, a compound that can generate zinc oxide upon firing, metallic zinc, a zinc alloy, or a mixture thereof, and
(iv) an organic medium in which the components (i) through (iii) are dispersed,
the organic medium comprising about 0.01 to about 10% by weight based on total composition of a surfactant having a formula
(R1)(R2)(R3)(R4)N⁺X⁻,
wherein each of R1, R2, R3, R4 is separately an alkyl, alkyl/aryl, alkyl/heteroaryl, or polyethylene glycol group, at least one of R1, R2, R3, or R4 is a polyethylene glycol or oleyl amide group, and X⁻ is a halide, alkylsulfonate, alkylsulfate, alkylphosphate, alkylcarboxylate, arylcarboxylate, dodecylbenzenesulfonate, dicyanamide, bis(2,4,4-trimethylpentyl)phosphinate, dibutyl phosphate, hexafluorophosphate, or a combination thereof.

14. The article of claim 13, wherein the substrate is a semiconductor substrate and the article is a semiconductor device.

15. The article of claim 14, wherein the semiconductor device is a photovoltaic cell.

16. The article of claim 14, wherein the substrate is a silicon wafer.

17. The article of claim 14, wherein the substrate comprises an insulating layer present on the first major surface and the paste composition is deposited on the insulating layer.

18. The article of claim 13, wherein the paste composition has been fired to remove the organic medium and form an electrode having electrical contact with the substrate.

19. A process comprising:
(a) providing a substrate having a first major surface;
(b) applying a paste composition onto a preselected portion of the first major surface, wherein the paste composition comprises in admixture:
i) about 75 to about 99% by weight based on solids of a source of an electrically conductive metal;
ii) about 0.1 to about 10% by weight based on solids of at least one glass component;
iii) 0 to about 15% by weight based on solids of an optional zinc-containing additive, that is at least one of zinc oxide, a compound that generates zinc oxide upon firing, zinc metal, a zinc alloy, or a mixture thereof, and
iv) an organic medium in which the components i) through iii) are dispersed, the organic medium comprising about 0.01 to about 10% by weight based on total composition of a surfactant having a formula
(R1)(R2)(R3)(R4)N⁺X⁻,
wherein each of R1, R2, R3, R4 is separately an alkyl, alkyl/aryl, alkyl/heteroaryl, or polyethylene glycol group, at least one of R1, R2, R3, or R4 is a polyethylene glycol or oleyl amide group, and X⁻ is a halide, alkylsulfonate, alkylsulfate, alkylphosphate, alkylcarboxylate, arylcarboxylate, dodecylbenzenesulfonate, dicyanamide, bis(2,4,4-trimethylpentyl)phosphinate, dibutyl phosphate, hexafluorophosphate, or a combination thereof, and
(c) firing the substrate and the paste composition, whereby the organic medium of the paste composition is removed and an electrode is formed that has electrical contact with the substrate.

20. The process of claim 19, wherein an insulating layer is present on the first major surface and the paste composition is applied over the insulating layer.

21. The process of claim 20, wherein the insulating layer comprises at least one of aluminum oxide, titanium oxide, silicon nitride, SiNx:H, silicon oxide, or silicon oxide/titanium oxide.

22. The process of claim 20, wherein the insulating layer is a naturally occurring layer.

23. The process of claim 20, wherein the paste composition is applied onto the first major surface in a preselected pattern.

24. The process of claim 19, wherein the firing is carried out in air or an oxygen-containing atmosphere.

25. The process of claim 19, wherein the source of electrically conductive metal is finely divided silver particles.

26. An article fabricated using the process of claim 19.

27. A photovoltaic cell fabricated using the process of claim 20.
